(19) United States
(12) Patent Application Publication
(10) Pub. No.: US 2006/0073614 A1
(43) Pub. Date: Apr. 6, 2006

(54) Ferroelectric capacitor structure and manufacturing method thereof

(76) Inventor: Kousuke Hara, Tokyo (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/102,921

(22) Filed: Apr. 11, 2005

(30) Foreign Application Priority Data
Oct. 4, 2004 (JP) 290945/2004

(51) Int. Cl. H01L 21/00

(52) U.S. Cl. 438/3

(57) ABSTRACT

The present invention provides a ferroelectric capacitor structure comprising a ferroelectric capacitor which is constituted in such a manner that a lower electrode is formed, a ferroelectric film is formed on the lower electrode and an upper electrode is formed on the ferroelectric film, and which is formed in a predetermined pattern; a hydrogen diffusion barrier film formed on the ferroelectric capacitor; an interlayer insulating film formed on the hydrogen diffusion barrier film; and a contact hole for connecting the upper electrode and an upper metal wiring layer. In the ferroelectric capacitor structure, etching of the interlayer insulating film is performed using a gas containing a fluorine element, and etching of the hydrogen diffusion barrier film is carried out using a mixed gas of at least a gas containing a reductive group and a halogen gas, or a halogen gas having a reductive group as a constituent substance.

### BACKGROUND OF THE INVENTION

1. Field of the Invention

The present invention relates to a semiconductor integrated circuit, and particularly to a ferroelectric capacitor structure and a manufacturing method thereof.

2. Description of the Related Art

Research on various memory cells has been pursued in recent years. As one of them, may be mentioned, a non-volatile memory using a ferroelectric film. The non-volatile memory is capable of rewriting at high speed because it makes use of high-speed polarization inversion of a ferroelectric capacitor and is low in power consumption because it makes use of the amount of residual polarization. Therefore, the present non-volatile memory is expected as a memory having superiority. The ferroelectric capacitor is generally constituted of an upper electrode, a ferroelectric film and a lower electrode in a laminated form.

There has heretofore been known a method of defining an opening using an F system gas for etching of an interlayer insulating film and using a Cl system gas or a mixed gas of the Cl system gas and F system gas upon contact hole etching used for connecting a ferroelectric capacitor and an upper metal wiring layer (refer to, for example, Japanese Unexamined Patent Publication No. 2000-133633).

There is also known a method having a process step for selectively etching an Al₂O₃ film provided on a silicon substrate by using an etching gas with CHF₃/CO as a principal component and a process step for anisotropically selectively etching a silicon substrate by using an etching gas with Cl₂ and/or HBr as a principal component (refer to, for example, Japanese Unexamined Patent Publication No. Hei 6(1994)-208975).

Further, there is known a plasma etching method of a platinum electrode of a semiconductor device containing the platinum electrode, using etching gases containing nitrogen and halogen, and an inert gas, BCl₃, HBr, SiCl₄, and gases selected from a mixture of these, as etching gases (refer to, for example, Japanese Patent Publication No. 2002-537645).

When, however, a Cl₂/CF₄/Ar gas system or a Cl₂/O₂/CF₄/Ar gas system is used upon the etching of the hydrogen diffusion barrier film as described in Japanese Unexamined Patent Publication 2000-133633, an etching rate of an upper electrode of the ferroelectric capacitor and an etching rate of the hydrogen diffusion barrier film become almost the same. Therefore, when such a gas system is used, the upper electrode is chipped off by an amount at overetching so that leaving the upper electrode behind becomes very difficult upon the etching of the hydrogen diffusion barrier film as shown in FIG. 1. As a result, a serious problem arose in that the upper electrode was eliminated to expose a ferroelectric film and H₂O and H₂ were intruded from a contact hole section to noticeably deteriorate ferroelectric capacitor characteristics.

Although the method for etching silicon, which has been described in Japanese Unexamined Patent Publication No. Hei 6(1994)-208975 makes use of the reducing gas as the etching gas, its aim is to prevent deterioration in shape of a deep trench due to etching of the silicon substrate corresponding to a trench upper portion upon forming the deep trench. That is, the aim thereof is to make it possible to form a trench small in opening dimension and deep and is not one relevant to an etching method for fabricating a ferroelectric capacitor.

Further, although the platinum-electrode plasma etching method described in Japanese Patent Publication No. 2002-537645 makes use of the reducing gas as the etching gas, its aim is to provide a method of plasma etching a platinum electrode layer, which is used for manufacturing a high-density integrated circuit type semiconductor device having a platinum electrode including high-angle platinum shape anisotropy. This method is not one related to the method for manufacturing the ferroelectric capacitor.

### SUMMARY OF THE INVENTION

The present invention has been made in view of the foregoing. It is therefore an object of the present invention to provide a ferroelectric capacitor structure and its manufacturing method capable of suppressing chipping off of an upper electrode of a ferroelectric capacitor, eliminating damage to a ferroelectric film and obtaining capacitor characteristics in which a dielectric polarization rate is high.

In order to solve the above problems, etching of a hydrogen diffusion barrier film is carried out using an etching gas containing a reducing gas. Thus, the present invention was capable of solving the problems.

That is, the present invention is characterized in that such constitutions as shown below are provided.

(1) A ferroelectric capacitor structure comprising a ferroelectric capacitor which is constituted in such a manner that a ferroelectric film is formed on a lower electrode and an upper electrode is formed on the ferroelectric film and which is formed in a predetermined pattern; a hydrogen diffusion barrier film formed on the ferroelectric capacitor; an interlayer insulating film formed on the hydrogen diffusion barrier film; and a contact hole for connecting the upper electrode and an upper metal wiring layer, wherein etching of the interlayer insulating film is performed using a gas containing a fluorine element, and etching of the hydrogen diffusion barrier film is carried out using a mixed gas of at least a gas containing a reductive group and a halogen gas, or a halogen gas having a reductive group as a constituent substance.

(2) The ferroelectric capacitor structure wherein the gas containing the reductive group or the halogen gas having the reductive group contains at least boron (B) or carbon (C).

(3) The ferroelectric capacitor structure wherein a material for the upper electrode is platinum (Pt), and a material for the ferroelectric film is lead zirconate titanate (PZT) compounds or strontium bismuth tantalate (SBT) compounds.

(4) The ferroelectric capacitor structure wherein a material for the hydrogen diffusion barrier film is alumina (Al₂O₃), strontium titanate (STO) or other metal oxides.

(5) The ferroelectric capacitor structure fabricated under which a flow rate of BCl₃ under the use of a BCl₃/Cl₂ mixed gas is set to 70% or more, and bias RF power for controlling ion energy applied to a cathode electrode is set to 70 W or less upon the etching of the hydrogen diffusion barrier film.

(6) A method for manufacturing a ferroelectric capacitor structure, comprising the steps of forming a lower electrode, forming, in a predetermined pattern, a ferroelectric capacitor constituted in such a manner that a ferroelectric film is formed on the lower electrode and an upper electrode is formed on the ferroelectric film, forming a hydrogen diffusion barrier film on the ferroelectric capacitor, forming an interlayer insulating film on the hydrogen diffusion barrier film, forming a contact hole for connecting the upper electrode and an upper metal wiring layer, performing etching of the interlayer insulating film using a gas containing a fluorine element, and performing etching of the hydrogen diffusion barrier film, using a mixed gas of at least a gas containing a reductive group and a halogen gas, or a halogen gas having a reductive group as a constituent substance.

(7) The method wherein the gas containing the reductive group or the halogen gas having the reductive group contains at least boron (B) or carbon (C).

(8) The method wherein a material for the upper electrode is platinum (Pt), and a material for the ferroelectric film is lead zirconate titanate (PZT) compounds or strontium bismuth tantalate (SBT) compounds.

(9) The method wherein a material for the hydrogen diffusion barrier film is alumina (Al₂O₃), strontium titanate (STO) or other metal oxides.

(10) The method wherein upon the etching of the hydrogen diffusion barrier film, a flow rate of BCl₃ under the use of a BCl₃/Cl₂ mixed gas is set to 70% or more, and bias RF power for controlling ion energy applied to a cathode electrode is set to 70 W or less.

According to the ferroelectric capacitor structure and its manufacturing method according to the present invention, the chipping off of an upper electrode of a ferroelectric capacitor is suppressed and no ferroelectric film is damaged. It is therefore possible to obtain capacitor characteristics in which a dielectric polarization rate is high. In particular, an advantageous effect is brought about in that the yields of a ferroelectric capacitor type semiconductor memory brought into high integration can be enhanced. Further, an advantageous effect is brought about in that reliability can be enhanced.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a diagram showing problems at the formation of a ferroelectric capacitor;

FIG. 2 is a diagram illustrating a structure prior to the formation of the ferroelectric capacitor;

FIG. 3 is a diagram depicting a structure subsequent to the formation of the ferroelectric capacitor;

FIG. 4 is a diagram showing a structure prior to etching of a hydrogen diffusion barrier film;

FIG. 5 is a diagram depicting dependence of Pt and Al₂O₃ etching rates on a flow rate of BCl₃;

FIG. 6 is a diagram illustrating dependence of Pt and Al₂O₃ etching rates on RF power;

FIG. 7 is a diagram depicting Al₂O₃/Pt etching selection ratios; and

FIG. 8 is a diagram showing a structure subsequent to the formation of a ferroelectric capacitor according to a first embodiment.

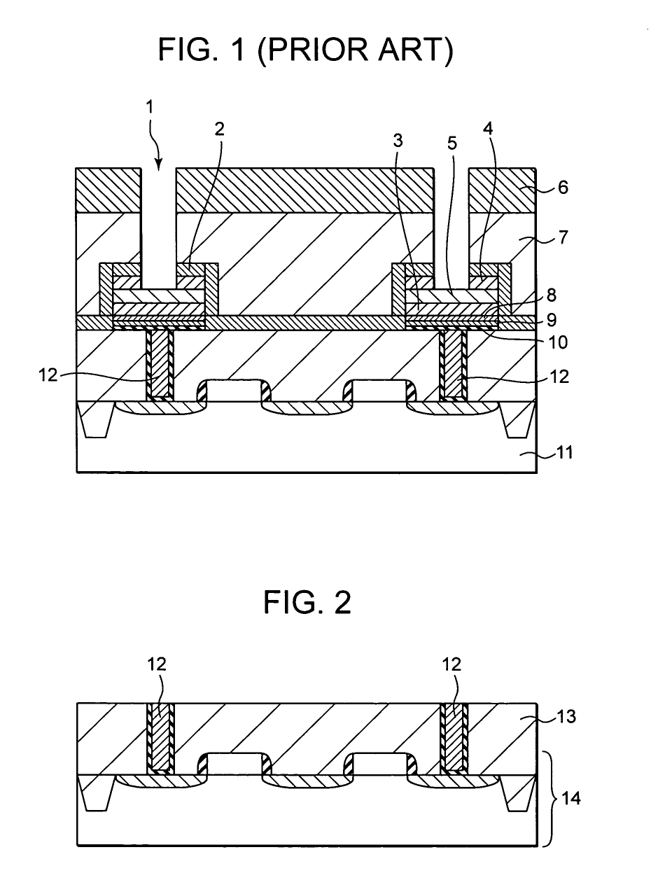

### DETAILED DESCRIPTION OF THE PREFERRED EMBODIMENTS

Respective constituent requirements of the present invention will hereinafter be described in detail.

In the present invention, the term “reductive group” means an element which reacts with oxygen. Since the present invention is characterized in that each of metal oxides is used as a material for a hydrogen diffusion barrier film, the element necessary to remove oxygen contained in the metal oxides referred to above is defined as “reductive group”. In the present invention, for example, boron (B) or carbon (C) or the like is used as the above “reductive group”. In this case, however, boron (B) or carbon (C) referred to above is constituted as BxOy, CO or CO₂ or the like, and oxygen is removed therefrom.

As specific examples of etching gases for an interlayer insulating film, which can be used in the present invention, may be mentioned, for example, those referred to below. That is, gases such as CHF₃, CF₄, C₄F₈, C₅F₈, C₄F₆, CH₂F₂, SF₆, etc. can be used.

Further, as specific examples of the etching gases for the hydrogen diffusion barrier film, which can be used in the present invention, may be mentioned, for example, those referred to below. That is, each of gases such as CF₄/Cl₂, BCl₃/Cl₂, etc. can be used as a mixed gas of a gas and a halogen gas each containing a reductive group. As the halogen gas having the reductive group as a constituent substance, each of gases such as BCl₃, CCl₄, CF₂Cl₂, etc. can be used. However, the present invention is not limited to these gases. Cl referred to above is substitutable with Br or I.

As a material for the hydrogen diffusion barrier film, which can be used in the present invention, may be mentioned, alumina (Al₂O₃), strontium titanate (STO) or other metal oxides, whereas as the metal oxides, may be mentioned, for example, a titanium oxide, a tantalum oxide, etc.

As a material for an upper electrode, which can be used in the present invention, may be mentioned, for example, Pt. As a material for a ferroelectric film, may be mentioned, for example, lead zirconate titanate (PZT) compounds or strontium bismuth tantalate (SBT) compounds. While Pt is generally being used as a material for a lower electrode, a laminated structure containing Pt or other conductive film may also be used in the present invention.

Incidentally, as to the spot to fabricate a capacitor structure, the capacitor structure is fabricated on a plug to make conduction to the lower electrode in the case of such a structure as illustrated in the present invention. The capacitor structure is fabricated on an insulating film in the case where contact is made from above a capacitor similarly to the upper electrode.

According to a ferroelectric capacitor structure of the present invention and its fabrication method, the chipping off of an upper electrode of a ferroelectric capacitor is suppressed and no ferroelectric film is damaged. It is therefore possible to obtain capacitor characteristics in which a dielectric polarization rate is high. In particular, an advantageous effect is brought about in that the yields of a ferroelectric capacitor type semiconductor memory brought into high integration can be enhanced. Further, an advantageous effect is brought about in that reliability can be enhanced.

Also, according to the present invention, an advantageous effect is brought about in that an etching selection ratio to Pt is particularly enhanced in addition to the above effects.

Preferred embodiments showing a ferroelectric capacitor structure according to the present invention and its manufacturing method will hereinafter be described.

The embodiments of the present invention are explained below with reference to the accompanying drawings. However, a gas containing a fluorine (F) element, a gas containing a reductive group or a gas having a reductive group, and a halogen gas or the like are merely preferred illustrations within the scope of the present invention and by no means limited by the following.

### First Preferred Embodiment

A substrate structure at the formation of a ferroelectric capacitor, which is used in a ferroelectric capacitor structure of the present invention, is shown in FIG. 2. FIG. 2 shows a state in which, using a normal Si semiconductor process, device isolation, a diffusion layer and a transistor element are formed in an Si substrate, and an insulating film is formed and planarized, followed by formation of plugs each connected to a lower electrode of the capacitor. A subsequent process step corresponds to the step of forming the capacitor.

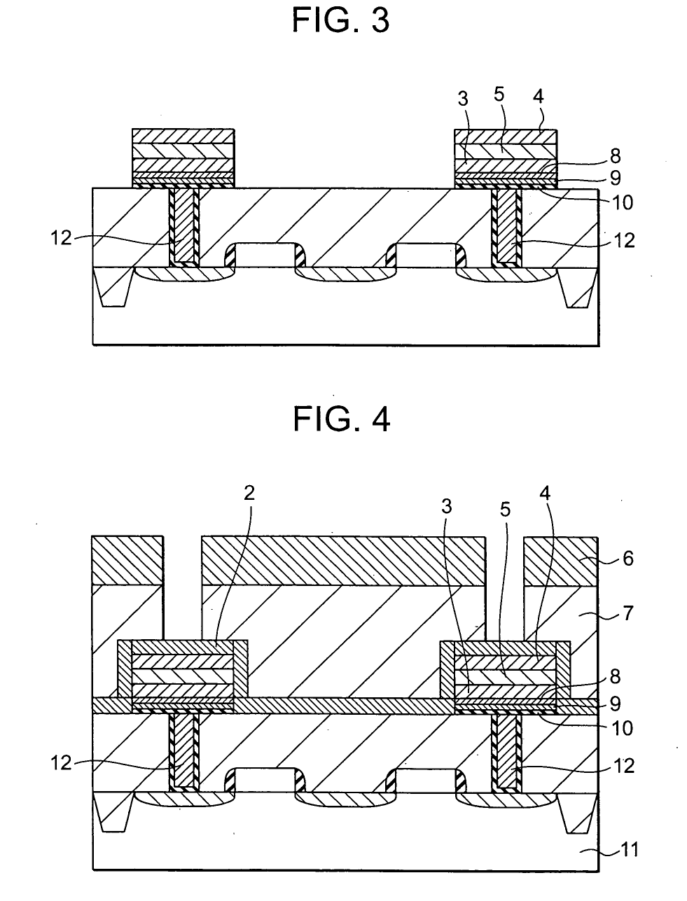

An antioxidant film for the plugs, which is constituted as part of the lower electrode is first formed. Although several types of antioxidant films are known, a TiAlN film is used in the present embodiment. An Ir film and an IrO₂ film are formed as adhesive layers in continuation with the TiAlN film. Thereafter, a Pt film, which serves as the lower electrode, a film of strontium bismuth tantalate (SBT), which serves as a ferroelectric film, and a Pt film which serves as the upper electrode, are sequentially formed. Thereafter, an SiO₂ film which serves as an etching mask, is formed. Next, the etching mask is first processed using the normal lithography method. Subsequently, a step for removing a resist is performed, and the ferroelectric capacitor structure comprised of the Pt film, strontium bismuth tantalate (SBT) film, Pt film, IrO₂ film, Ir film and TiAlN film as viewed from the above layer is patterned by a dry etching method with SIO₂ as the mask. After the patterning thereof, SiO₂ formed as the etching mask is removed. A structure subsequent to the formation of the ferroelectric capacitor is shown in FIG. 3.

A detailed description will next be made of, as an example, a case in which an Al₂O₃ film is formed as a hydrogen diffusion barrier film. After the ferroelectric capacitor has been covered with Al₂O₃, an SiO₂ interlayer insulating film is deposited. Next, each of contact hole patterns, which is used for connecting the upper electrode of the ferroelectric capacitor and an unillustrated metal wiring layer, is formed using a lithography method. First, the interlayer insulating film is etched using a CHF₃/CF₄/Ar gas with the hydrogen diffusion barrier film as an etching stopper layer. A structure prior to the etching of the hydrogen diffusion barrier film is shown in FIG. 4.

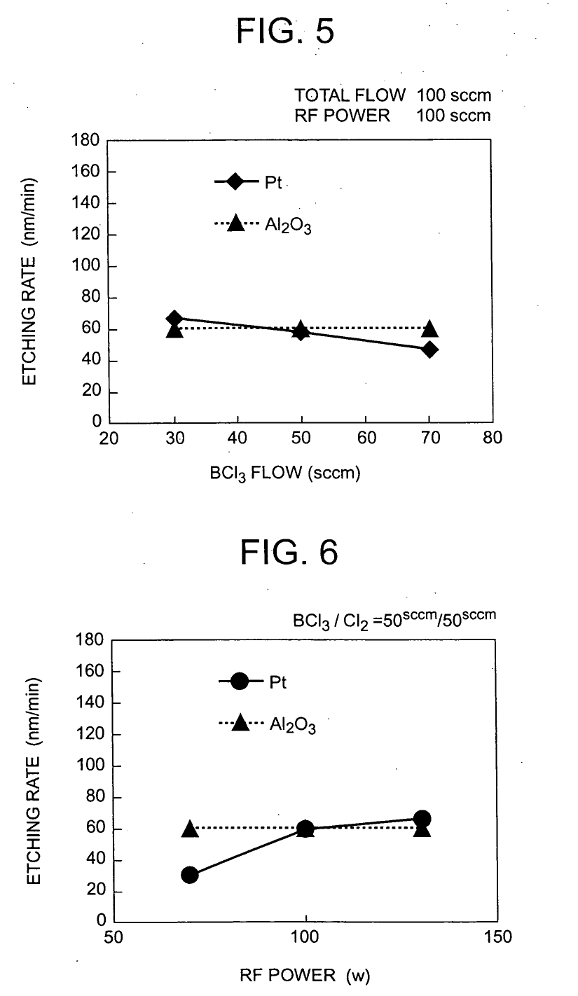

The etching of the hydrogen diffusion barrier film was done in a BCl₃/Cl₂ mixed gas system by using an ECR sheet-fed wafer plasma etcher. A result of calculations of etching rates of Al₂O₃ and Pt at the time that a flow rate of BCl₃/Cl₂ is changed to 30 sccm/70 sccm, 50 sccm/50 sccm, and 70 sccm/30 sccm is shown in FIG. 5. FIG. 5 is a diagram, showing dependence of the etching rates of Pt and Al₂O₃ on the flow rate of BCl₃, in which the flow of BCl₃ (sccm) is plotted on the horizontal axis and the etching rate (nm/min) is plotted on the vertical axis. It is understood from FIG. 5 that a selection ratio is enhanced where the flow rate of BCl₃ is set to 70% or more.

Next, a result of calculations of etching rates of Al₂O₃ and Pt at the time that bias RF power for controlling ion energy applied to a cathode electrode is changed to 70 W, 100 W and 130 W, is shown in FIG. 6. FIG. 6 is a diagram, showing dependence of the etching rates of Pt and Al₂O₃ on the RF power, in which the RF power (W) is plotted on the horizontal axis and the etching rate (nm/min) is plotted on the vertical axis. It is understood from FIG. 6 that a selection ratio is enhanced where the RF power is set to low power less than or equal to 70 W.

Incidentally, etching conditions used in the above method are represented as RF frequency: 13.56 MHz, discharge pressure: 1.33 Pa, electrode temperature: 40° C., and μ wave: 700 W.

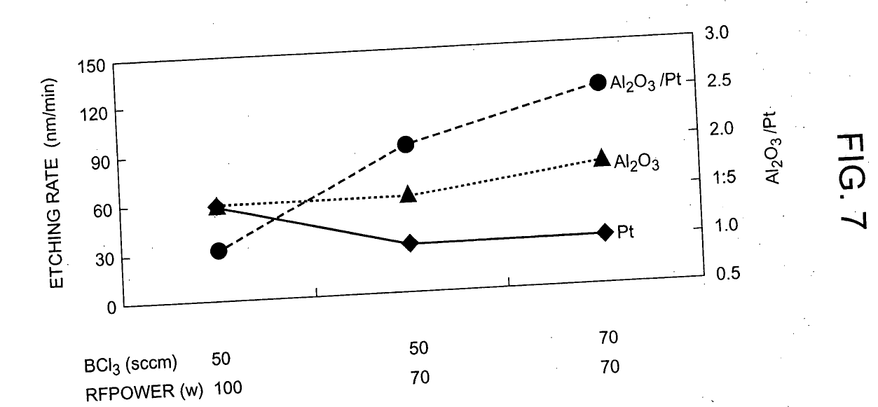

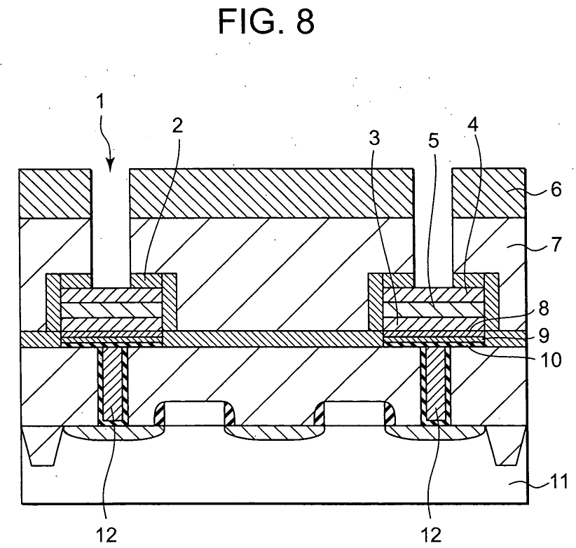

It is understood from above that since the Al₂O₃ etching is done on condition that the flow rate of BCl₃ under the use of the BCl₃/Cl₂ mixed gas is set to 70% or more and the bias RF power is set to 70 W or less, the etching selection ratio to Pt is enhanced up to 2.5 or more as shown in FIG. 7. FIG. 7 is a diagram, showing an Al₂O₃/Pt etching selection ratio, in which the BCL₃ flow/RF power is plotted on the horizontal axis and the etching rate (nm/min) is plotted as the vertical axis. As a result, it is understood that as shown in FIG. 8, the present invention can eliminate chipping off of Pt.

Next, a ferroelectric capacitor structure can be formed by carrying out an unillustrated wiring forming step.

The first embodiment has explained above a case in which Al₂O₃ is used as the hydrogen diffusion barrier film.

However, the present invention is not limited to Al₂O₃ as the hydrogen diffusion barrier film. It has been confirmed in the present invention that an excellent effect is brought about in that even when strontium titanate (STO), or a metal oxide like a titanium oxide or a tantalum oxide is used as the material for the hydrogen diffusion barrier film in place of alumina (Al₂O₃), the etching selection ratio is enhanced in a manner similar to the use of alumina (Al₂O₃).

Although the CHF₃/CF₄/Ar gas is used as the etching gas for the interlayer insulating film in the first embodiment, the present invention is not limited to the gas. All of the conventionally known etching gases for the interlayer insulating film can be used in the implementation of the present invention.

Even when gases such as C₄F₈, C₅F₈, C₄F₆, CH₂F₂, SF₆, etc. are used as other ones, similar effects can be obtained.

Further, although the BCl₃/Cl₂ mixed gas has been used as the etching gas for the hydrogen diffusion barrier film in the first embodiment, it can be substituted with other gas containing the reductive group in the present invention. Even in the case where BCl₃ is substituted with CCl₄, exactly the same effects can be obtained.

The etcher is not limited to the ECR sheet-fed wafer plasma etcher either and all means known to date can be used.

While the present invention has been described with reference to the illustrative embodiment, this description is not intended to be construed in a limiting sense. Various modifications of the illustrative embodiments will be apparent to those skilled in the art on reference to this description. It is therefore contemplated that the appended claims will cover any such modifications or embodiments as fall within the true scope of the invention.

What is claimed is:

1. A ferroelectric capacitor structure comprising:
a ferroelectric capacitor constituted in such a manner that a ferroelectric film is formed on a lower electrode and an upper electrode is formed on the ferroelectric film, said ferroelectric capacitor being formed in a predetermined pattern;
a hydrogen diffusion barrier film formed on the ferroelectric capacitor;
an interlayer insulating film formed on the hydrogen diffusion barrier film; and
a contact hole for connecting the upper electrode and an upper metal wiring layer,
wherein etching of the interlayer insulating film is performed using a gas containing a fluorine element, and etching of the hydrogen diffusion barrier film is carried out using a mixed gas of at least a gas containing a reductive group and a halogen gas, or a halogen gas having a reductive group as a constituent substance.

2. The ferroelectric capacitor structure according to claim 1, wherein the gas containing the reductive group or the halogen gas having the reductive group contains at least boron (B) or carbon (C).

3. The ferroelectric capacitor structure according to claim 1, wherein a material for the upper electrode is platinum (Pt), and a material for the ferroelectric film is lead zirconate titanate (PZT) compounds or strontium bismuth tantalate (SBT) compounds.

4. The ferroelectric capacitor structure according to claim 1, wherein a material for the hydrogen diffusion barrier film is alumina (Al₂O₃), strontium titanate (STO) or other metal oxides.

5. The ferroelectric capacitor structure according to claim 1, which is fabricated under which a flow rate of BCl₃ under the use of a BCl₃/Cl₂ mixed gas is set to 70% or more, and bias RF power for controlling ion energy applied to a cathode electrode is set to 70 W or less upon the etching of the hydrogen diffusion barrier film.

6. A method for manufacturing a ferroelectric capacitor structure, comprising the steps of:
forming, in a predetermined pattern, a ferroelectric capacitor constituted in such a manner that a lower electrode is formed, a ferroelectric film is formed on the lower electrode and an upper electrode is formed on the ferroelectric film;
forming a hydrogen diffusion barrier film on the ferroelectric capacitor;
forming an interlayer insulating film on the hydrogen diffusion barrier film;
forming a contact hole for connecting the upper electrode and an upper metal wiring layer;
performing etching of the interlayer insulating film using a gas containing a fluorine element; and
performing etching of the hydrogen diffusion barrier film, using a mixed gas of at least a gas containing a reductive group and a halogen gas, or a halogen gas having a reductive group as a constituent substance.

7. The method according to claim 6, wherein the gas containing the reductive group or the halogen gas having the reductive group contains at least boron (B) or carbon (C).

8. The method according to claim 6, wherein a material for the upper electrode is platinum (Pt), and a material for the ferroelectric film is lead zirconate titanate (PZT) compounds or strontium bismuth tantalate (SBT) compounds.

9. The method according to claim 6, wherein a material for the hydrogen diffusion barrier film is alumina (Al₂O₃), strontium titanate (STO) or other metal oxides.

10. The method according to claim 6, wherein upon the etching of the hydrogen diffusion barrier film, a flow rate of BCl₃ under the use of a BCl₃/Cl₂ mixed gas is set to 70% or more, and bias RF power for controlling ion energy applied to a cathode electrode is set to 70 W or less upon the etching of the hydrogen diffusion barrier film.
